(19) United States
(12) Patent Application Publication
(10) Pub. No.: US 2016/0049398 A1
(43) Pub. Date: Feb. 18, 2016

(54) SEMICONDUCTOR DEVICE

(71) Applicant: SAMSUNG ELECTRONICS CO., LTD., Suwon-si (KR)

(72) Inventors: Sung-Ho JANG, Seoul (KR); Tae-Ho LEE, Yongin-si (KR); Jung-Bun LEE, Ansan-si (KR)

(21) Appl. No.: 14/926,223

(22) Filed: Oct. 29, 2015

Related U.S. Application Data
(62) Division of application No. 14/182,876, filed on Feb. 18, 2014.

(30) Foreign Application Priority Data
Mar. 4, 2013 (KR) 10-2013-0022905

(51) Int. Cl. H01L 27/092; H01L 29/06

(52) U.S. Cl. CPC H01L 27/092; H01L 29/0649

(57) ABSTRACT

A semiconductor device including a substrate including an NMOS region and a PMOS region; first and second gate dielectrics on the NMOS and PMOS regions of the substrate and including a high-k dielectric material; a first gate structure on the first gate dielectric and including a sequentially stacked first n-type metal layer pattern and first electrode layer pattern; a second gate structure on the second gate dielectric and including a sequentially stacked p-type metal layer pattern, second n-type metal layer pattern, and second electrode layer pattern; first and second spacers on sidewalls of the first and second gate structures; a first offset pattern between the first gate structure and the first spacer; and a second offset pattern between the second gate structure and the second spacer, the second offset pattern being on the sidewalls of the second gate structure excluding sidewalls of the p-type metal layer pattern.

### CROSS-REFERENCE TO RELATED APPLICATIONS

This is a divisional application based on pending U.S. patent application Ser. No. 14/182,876, filed on Feb. 18, 2014, the entire contents of which is hereby incorporated by reference.

Korean Patent Application No. 10-2013-0022905, filed on Mar. 4, 2013, in the Korean Intellectual Property Office, and entitled: “Semiconductor Device,” is incorporated by reference herein in its entirety.

### BACKGROUND

1. Field

Embodiments relate to a semiconductor device.

2. Description of Related Art

Integration of a semiconductor device increases may include using a CMOS device structure in which a high dielectric material is used as a gate dielectric, and an NMOS device and a PMOS device include metal gate electrodes having different conductivity type from each other in order to implement a dual work function.

### SUMMARY

Embodiments are directed to a semiconductor device.

The embodiments may be realized by providing a semiconductor device including a substrate including an NMOS region and a PMOS region; first and second gate dielectrics on the NMOS and PMOS regions of the substrate and including a high-k dielectric material; a first gate structure on the first gate dielectric and including a sequentially stacked first n-type metal layer pattern and first electrode layer pattern; a second gate structure on the second gate dielectric and including a sequentially stacked p-type metal layer pattern, second n-type metal layer pattern, and second electrode layer pattern; first and second spacers on sidewalls of the first and second gate structures; a first offset pattern between the first gate structure and the first spacer; and a second offset pattern between the second gate structure and the second spacer, the second offset pattern being on the sidewalls of the second gate structure excluding sidewalls of the p-type metal layer pattern.

The p-type metal layer pattern may have a width greater than a width of the second n-type metal layer pattern.

A distance between an outer side surface of the second offset pattern and a side surface of the p-type metal layer pattern may be represented by A, a thickness of the second offset pattern may be represented by d, and A may satisfy the following relation: 0≦A≦d.

The second offset pattern may be in contact with a top edge of the p-type metal layer pattern.

A side surface of the p-type metal layer pattern may be in contact with the second spacer.

The semiconductor device may further include a first insulating layer pattern between the first offset pattern and the first spacer, and a second insulating layer pattern between the second offset pattern and the second spacer.

The second insulating layer pattern may be in contact with a side surface of the p-type metal layer pattern.

The semiconductor device may further include a first barrier metal layer pattern between the first n-type metal layer pattern and the first electrode layer pattern, and a second barrier metal layer pattern between the second n-type metal layer pattern and the second electrode layer pattern.

The semiconductor device may further include a first polysilicon layer pattern between the first n-type metal layer pattern and the first barrier metal layer pattern, and a second polysilicon layer pattern between the second n-type metal layer pattern and the second barrier metal layer pattern.

The semiconductor device may further include a first insulating mask layer pattern on the first electrode layer pattern; and a second insulating mask layer pattern on the second electrode layer pattern.

The embodiments may also be realized by providing a semiconductor device including a substrate including an NMOS region and a PMOS region; first and second gate dielectrics on the NMOS and PMOS regions of the substrate and including a high-k dielectric material; a first gate structure on the first gate dielectric and including a sequentially stacked first n-type metal layer pattern and first electrode layer pattern; a second gate structure on the second gate dielectric and including a sequentially stacked p-type metal layer pattern, second n-type metal layer pattern, and second electrode layer pattern; first and second spacers on sidewalls of the first and second gate structures; a first offset pattern between the first gate structure and the first spacer; and a second offset pattern between the second gate structure and the second spacer, the second offset pattern being on the sidewalls of the second gate structure excluding a portion of sidewalls of the p-type metal layer pattern.

The p-type metal layer pattern may include a first part having a same width as the second n-type metal layer pattern, and a second part having a width greater than the second n-type metal layer pattern.

The second offset pattern may be in contact with a side surface of the first part of the p-type metal layer pattern.

A distance between an outer side surface of the second offset pattern and a side surface of the second part of the p-type metal layer pattern may be represented by A, a thickness of the second offset pattern may be represented by d, and A may satisfy the following relation: 0≦A≦d.

The semiconductor device may further include a first insulating layer pattern between the first offset pattern and the first spacer, and a second insulating layer pattern between the second offset pattern and the second spacer, wherein the second insulating layer pattern is in contact with a side surface of the p-type metal layer pattern.

The embodiments may also be realized by providing a semiconductor device including a substrate including an NMOS region and a PMOS region; first and second gate dielectrics on the NMOS and PMOS regions of the substrate and including a high-k dielectric material; a first gate structure on the first gate dielectric and including a sequentially stacked first n-type metal layer pattern and first electrode layer pattern; a second gate structure on the second gate dielectric and including a sequentially stacked p-type metal layer pattern, second n-type metal layer pattern, and second electrode layer pattern; first and second spacers on sidewalls of the first and second gate structures; a first offset pattern between the first gate structure and the first spacer; and a second offset pattern between the second gate structure and the second spacer, the second offset pattern being on the sidewalls of the second gate structure, wherein the second offset pattern has a bottom surface that faces the substrate, the p-type metal layer pattern has a bottom surface that faces the substrate, and the bottom surface of the p-type metal layer pattern is closer to the substrate than the bottom surface of the second offset pattern.

The p-type metal layer pattern may have a top surface that faces away from the substrate, and the bottom surface of the second offset pattern may be closer to the substrate than the top surface of the p-type metal layer pattern.

An outer side surface of the second offset pattern may be aligned with a side surface of p-type metal layer pattern.

The p-type metal layer pattern may have a top surface that faces away from the substrate, and the bottom surface of the second offset pattern may be coplanar with the top surface of the p-type metal layer pattern.

A distance between an outer side surface of the second offset pattern and a side surface of the p-type metal layer pattern may be represented by A, a thickness of the second offset pattern may be represented by d, and A may satisfy the following relation: 0≦A≦d.

### BRIEF DESCRIPTION OF THE DRAWINGS

Features will be apparent to those of skill in the art by describing in detail exemplary embodiments with reference to the attached drawings in which:

FIGS. 1A to 14 illustrate cross-sectional views showing semiconductor devices in accordance with various embodiments;

FIGS. 15A to 26 illustrate cross-sectional views showing stages in methods of fabricating semiconductor devices in accordance with various embodiments;

FIG. 27 illustrates a schematic diagram showing a semiconductor module including a semiconductor device in accordance with various embodiments; and

FIG. 28 illustrates a block diagram of an electronic system including a semiconductor device in accordance with various embodiments

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

It will be understood that, although the terms first, second, A, B, etc. may be used herein in reference to elements of the invention, such elements should not be construed as limited by these terms. For example, a first element could be termed a second element, and a second element could be termed a first element, without departing from the scope of the present invention. Herein, the term “and/or” includes any and all combinations of one or more referents.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

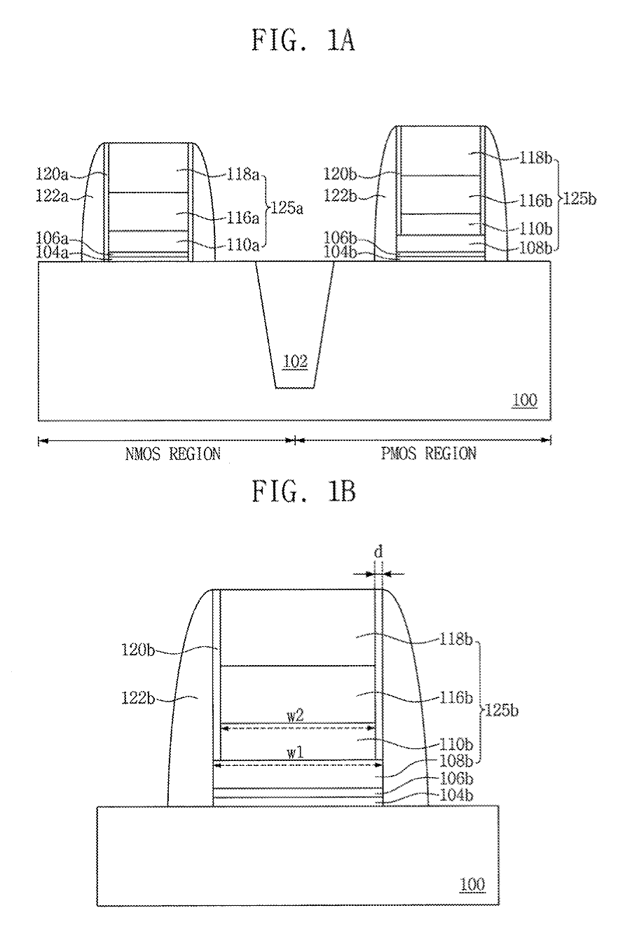

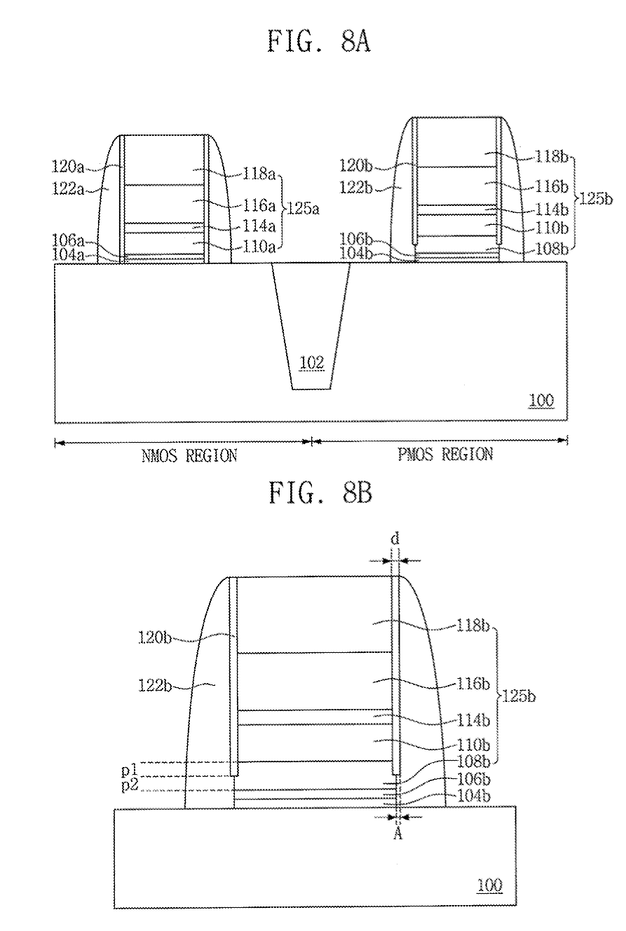

FIGS. 1A to 14 illustrate cross-sectional views of semiconductor devices in accordance with various embodiments. Here, FIGS. 1B, 4B, 5B, 6B, 7B, and 8B represent enlarged cross-sectional views of PMOS regions of FIGS. 1A, 4A, 5A, 6A, 7A, and 8A, respectively.

First, a semiconductor device in accordance with an embodiment will be described with reference to FIGS. 1A and 1B.

Referring to FIGS. 1A and 1B, a semiconductor device in accordance with an embodiment may include a substrate 100 (having an NMOS region and PMOS region), a trench isolation region 102 in the substrate 100, a first gate structure 125a on the NMOS region of the substrate 100, and a second gate structure 125b on the PMOS region of the substrate 100.

The substrate 100 may be a semiconductor substrate. For example, the substrate 100 may be a silicon substrate, a germanium substrate, a silicon-germanium substrate, or the like. The substrate 100 may include a P-well defining the NMOS region, and an N-well defining the PMOS region.

The trench isolation region 102 may be formed in the substrate 100 to define active regions. The trench isolation region 102 may include a field trench in the substrate 100, and an insulating layer filling the field trench. The insulating layer may include silicon oxide. The trench isolation region 102 may be formed between various devices, e.g., between two NMOS devices, between two PMOS devices, or between an NMOS device and a PMOS device.

First and second gate dielectrics 106a and 106b may be formed on the NMOS and PMOS regions of the substrate 100. The first and second gate dielectrics 106a and 106b may include a high-k dielectric material having a greater dielectric constant than silicon oxide. For example, the first and second gate dielectrics 106a and 106b may include at least one of high-k dielectric materials, such as Al₂O₃, HfO₂, HfSiO₂, ZrO₂, ZrSiO, LaO₂, and TiO₂.

First and second interlayer insulating layer patterns 104a and 104b may be formed between the substrate 100 and the first gate dielectric 106a, and between the substrate 100 and the second gate dielectric 106b, respectively. The first and second interlayer insulating layer patterns 104a and 104b may function to reduce interface traps between the substrate 100 and the first and second gate dielectrics 106a and 106b, and may help maintain the mobility of carriers. The first and second interlayer insulating layer patterns 104a and 104b may include, e.g., silicon oxide (SiOₓ) or silicon oxynitride (SiON).

The first gate structure 125a on the NMOS region of the substrate 100 may include a first n-type metal layer pattern 110a and a first electrode layer pattern 116a sequentially stacked on the first gate dielectric 106a. In addition, the first gate structure 125a may further include a first insulating mask layer pattern 118a on the first electrode layer pattern 116a.

The second gate structure 125b on the PMOS region of the substrate 100 may include a p-type metal layer pattern 108b, a second n-type metal layer pattern 110b, and a second electrode layer pattern 116b sequentially stacked on the second gate dielectric 106b. In addition, the second gate structure 125b may further include a second insulating mask layer pattern 118b on the second electrode layer pattern 116b.

A threshold voltage of a MOS device may be determined by a difference of work functions between a gate and a channel. Work function is a measured value of energy needed to emit an electron in a material into vacuum above the range of a material atom, when the electron is located at the Fermi level in the initial state. The unit for work function is electron volt (eV). The difference of work functions between the gate and the channel is basically an arithmetic difference between a work function of a gate material located closest to the channel area, and a work function of the channel material. In order to help prevent a Fermi level pinning phenomenon and acquire a low threshold voltage for both NMOS device and PMOS device, which is suitable a high performance low power device, it is desirable to use dual metal gate electrodes having different work function values with respect to the NMOS device and the PMOS device. An element for controlling a work function of a metal gate electrode may be selected from Al, O, C, N, F, or a combination thereof.

Accordingly, the threshold voltage of an NMOS device may be controlled by the first n-type metal layer pattern 110a on the first gate dielectric 106a, and the threshold voltage of a PMOS device may be controlled by the p-type metal layer pattern 108b on the second gate dielectric 106b.

The first n-type metal layer pattern 110a (controlling the threshold voltage of an NMOS device) and the second n-type metal layer patterns 110b (formed of the same layer as the first n-type metal layer pattern 110a) may be formed in a multi-layered structure in which a plurality of thin metal layers are stacked. For example, the first and second n-type metal layer patterns 110a and 110b may include at least one of TiN/TiON, Mg/TiN, TiN/Mg/TiN, La/TiN, TiN/La/TiN, Sr/TiN, and TiN/Sr/TiN. In an implementation, TaN may be used instead of TiN.

The p-type metal layer pattern 108b (controlling a threshold voltage of the PMOS device) may also be formed in a multi-layered structure in which a plurality of thin metal layers are stacked. For example, the p-type metal layer patterns 108b may include at least one of Al₂O₃/TiN, Al₂O₃/TaN, Al/TiN, Al/TaN, TiN/Al/TiN, TaN/Al/TaN, TiN/TiON, TaN/TiON, Ta/TiN, TaN/TiN, or the like.

The first electrode layer pattern 116a (provided as an electrical gate of the NMOS device) and the second electrode layer pattern 116b (provided as an electrical gate of the PMOS device) may include at least one of a metal such as tungsten (W), copper (Cu), and aluminum (Al), a conductive metal-nitride such as titanium nitride (TiN), tantalum nitride (TaN), tungsten nitride (WN), a conductive metal-semiconductor compound such as a metal silicide, or a transition metal such as titanium (Ti) or tantalum (Ta).

The first and second insulating mask layer patterns 118a and 118b (provided as a mask for gate-patterning) may include an insulating material, e.g., silicon nitride.

First and second spacers 122a and 122b may be formed on sidewalls of the first and second gate structures 125a and 125b. First and second offset patterns 120a and 120b may be between the first gate structure 125a and the first spacer 122a, and between the second gate structure 125b and the second spacer 122b, respectively.

The first and second spacers 122a and 122b may include silicon oxide. The first and second offset patterns 120a and 120b may function to control a distance between a gate and an LDD region. The first and second offset patterns 120a and 120b may include, e.g., silicon nitride, silicon oxide, or silicon oxynitride.

The second offset pattern 120b may be formed on the sidewalls of the second gate structure 125b excluding or except for sidewalls of the p-type metal layer pattern 108b. For example, the second offset pattern 120b may be on sidewalls of the second n-type metal layer pattern 110b, the second electrode layer pattern 116b, and the second insulating mask layer pattern 118b. In an implementation, the second offset pattern 120b may be on sidewalls of only the second n-type metal layer pattern 110b, the second electrode layer pattern 116b, and the second insulating mask layer pattern 118b. The second offset pattern 120b may cover at least a portion of a top edge of the p-type metal layer pattern 108b. In an implementation, the second offset pattern 120b may have a bottom surface that faces the substrate 100, the p-type metal layer pattern 108b may have a bottom surface that faces the substrate 100, and the bottom surface of the p-type metal layer pattern 108b may be closer to the substrate 100 than the bottom surface of the second offset pattern 120b. In an implementation, the p-type metal layer pattern 108b may have a top surface that faces away from the substrate 100, and the bottom surface of the second offset pattern 120b may be coplanar with the top surface of the p-type metal layer pattern 108b.

The p-type metal layer pattern 108b may have a width greater than that of the second n-type metal layer pattern 110b. For example, the width of the p-type metal layer pattern 108b may be represented by w1, the width of the second n-type metal layer pattern 110b may be represented by w2, the thickness of the second offset pattern 120b may be represented by d, and the width w1 of the p-type metal layer pattern 108b may satisfy the following relation: (w1=2d+w2).

In this case, a side, e.g., an outer side, of the second offset pattern 120b may be collinear or aligned with a side of the p-type metal layer pattern 108b.

The p-type metal layer pattern 108b may be selectively etched using the second offset pattern 120b in contact with the top edge of the p-type metal layer pattern 108b. Accordingly, in the process of etching the gates of the NMOS device and PMOS device having different heights of gate stacks, failure in a gate profile of the PMOS device (which may other otherwise occur due to the p-type metal layer pattern 108b of the PMOS device having a higher gate stack than the NMOS device not being etched) may be reduced and/or prevented. In addition, undercutting of the first n-type metal layer pattern 110a of the NMOS device due to an excessive etching process for gate-patterning of the PMOS device having a high gate stack may be reduced and/or prevented.

Hereinafter, semiconductor devices in accordance with various embodiments will be described around modified parts, and repeated explanations for the same parts as the aforementioned embodiments may be omitted.

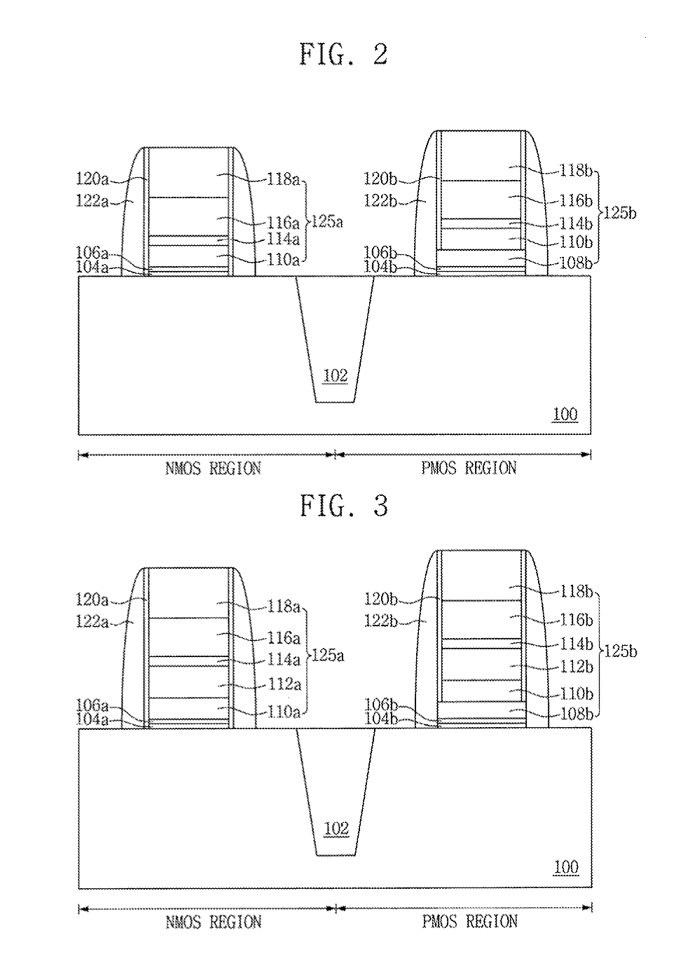

Referring to FIG. 2, a semiconductor device in accordance with an embodiment may include a substrate 100 having an NMOS region and a PMOS region, a trench isolation region 102 in the substrate 100, a first gate structure 125a on the NMOS region of the substrate 100, a second gate structure 125b on the PMOS region of the substrate 100, first and second spacers 122a and 122b on sidewalls of the first and second gate structures 125a and 125b, and first and second offset patterns 120a and 120b between the first gate structure 125a and the first spacer 122a, and between the second gate structure 125b and the second spacer 122b, respectively.

The first gate structure 125a on the NMOS region of the substrate 100 may include a first n-type metal layer pattern 110a, a first barrier metal layer pattern 114a, and a first electrode layer pattern 116a sequentially stacked on a first gate dielectric 106a having a high-k dielectric material. In addition, the first gate structure 125a may further include a first insulating mask layer pattern 118a on the first electrode layer pattern 116a.

The second gate structure 125b on the PMOS region of the substrate 100 may include a p-type metal layer pattern 108b, a second n-type metal layer pattern 110b, a second barrier metal layer pattern 114b, and a second electrode layer pattern 116b sequentially stacked on a second gate dielectric 106b having a high-k dielectric material. In addition, the second gate structure 125b may further include a second insulating mask layer pattern 118b on the second electrode layer pattern 116b. The p-type metal layer pattern 108b may have a width greater than that of the second n-type metal layer pattern 110b.

The first and second n-type metal layer patterns 110a and 110b and the p-type metal layer pattern 108b may be formed in a multi-layered structure in which a plurality of thin metal layers are stacked.

The first and second electrode layer patterns 116a and 116b may include a metal, such as tungsten (W), copper (Cu), or aluminum (Al).

The first and second barrier metal layer patterns 114a and 114b may function to lower a potential barrier of a contact surface between the first and second electrode layer patterns 116a and 116b and the first and second n-type metal layer patterns 110a and 110b. The first and second barrier metal layer patterns 114a and 114b may include a conductive metal-nitride, such as titanium nitride (TiN), tantalum nitride (TaN), or tungsten nitride (WN).

The second offset pattern 120b may be formed on the sidewalls of the second gate structure 125b, excluding sidewalls of the p-type metal layer pattern 108b. For example, the second offset pattern 120b may be on sidewalls of the second n-type metal layer pattern 110b, the second barrier metal layer pattern 114b, the second electrode layer pattern 116b, and the second insulating mask layer pattern 118b. In an implementation, the second offset pattern 120b may be on sidewalls of only the second n-type metal layer pattern 110b, the second barrier metal layer pattern 114b, the second electrode layer pattern 116b, and the second insulating mask layer pattern 118b. The second offset pattern 120b may cover at least a portion of a top edge of the p-type metal layer pattern 108b. In an implementation, the second offset pattern 120b may have a bottom surface that faces the substrate 100, the p-type metal layer pattern 108b may have a bottom surface that faces the substrate 100, and the bottom surface of the p-type metal layer pattern 108b may be closer to the substrate 100 than the bottom surface of the second offset pattern 120b. In an implementation, the p-type metal layer pattern 108b may have a top surface that faces away from the substrate 100, and the bottom surface of the second offset pattern 120b may be coplanar with the top surface of the p-type metal layer pattern 108b.

Referring to FIG. 3, a semiconductor device in accordance with an embodiment may include a substrate 100 having an NMOS region and a PMOS region, a trench isolation region 102 in the substrate 100, a first gate structure 125a on the NMOS region of the substrate 100, a second gate structure 125b on the PMOS region of the substrate 100, first and second spacers 122a and 122b on sidewalls of the first and second gate structures 125a and 125b, and first and second offset patterns 120a and 120b between the first gate structure 125a and the first spacer 122a, and between the second gate structure 125b and the second spacer 122b, respectively.

The first gate structure 125a on the NMOS region of the substrate 100 may include a first n-type metal layer pattern 110a, a first polysilicon layer pattern 112a, a first barrier metal layer pattern 114a, a first electrode layer pattern 116a, and a first insulating mask layer pattern 118a, sequentially stacked on a first gate dielectric 106a (that includes a high-k dielectric material).

The second gate structure 125b on the PMOS region of the substrate 100 may include a p-type metal layer pattern 108b, a second n-type metal layer pattern 110b, a second polysilicon layer pattern 112b, a second barrier metal layer pattern 114b, a second electrode layer pattern 116b, and a second insulating mask layer pattern 118b, sequentially stacked on a second gate dielectric 106b (that includes a high-k dielectric material). The p-type metal layer pattern 108b may have a width greater than that of the second n-type metal layer pattern 110b.

The first and second barrier metal layer patterns 114a and 114b may form an ohmic contact between the first and second electrode layer patterns 116a and 116b and the underlying first and second polysilicon layer patterns 112a and 112b. The first and second barrier metal layer patterns 114a and 114b may include at least one of a conductive metal-nitride such as TiN, TaN, and WN, or a conductive metal-semiconductor compound such as a metal silicide.

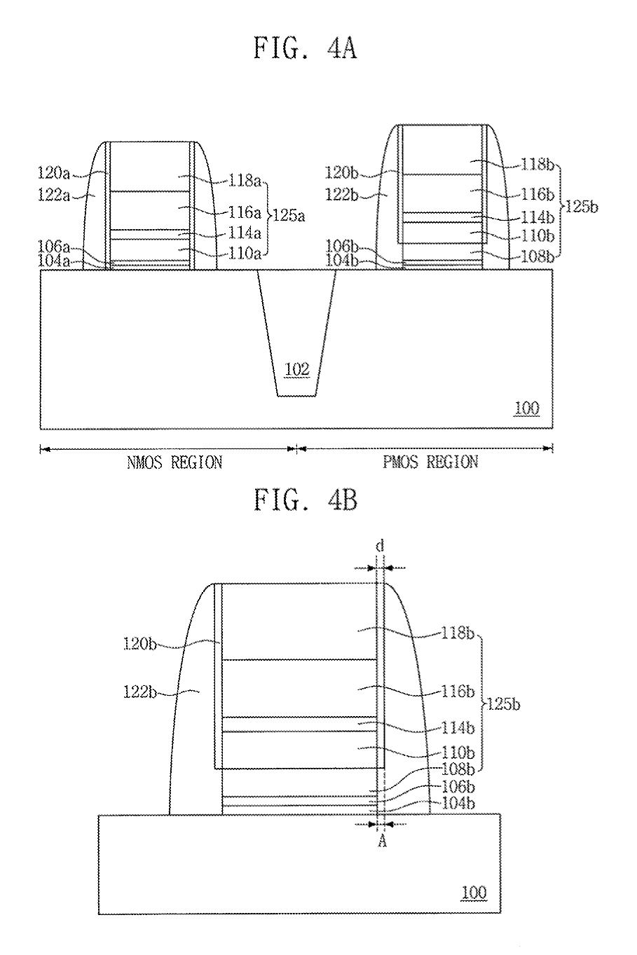

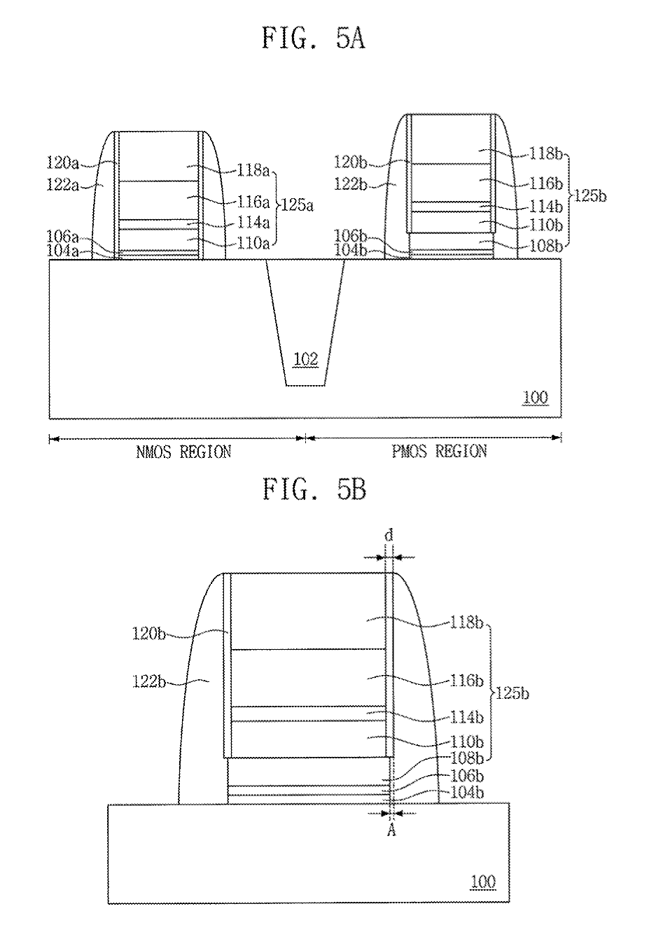

Referring to FIGS. 4A to 5B, a semiconductor device in accordance with an embodiment may include a substrate 100 having an NMOS region and a PMOS region, a trench isolation region 102 in the substrate 100, a first gate structure 125a on the NMOS region of the substrate 100, a second gate structure 125b on the PMOS region of the substrate 100, first and second spacers 122a and 122b on sidewalls of the first and second gate structures 125a and 125b, and first and second offset patterns 120a and 120b between the first gate structure 125a and the first spacer 122a, and between the second gate structure 125b and the second spacer 122b, respectively.

The first gate structure 125a on the NMOS region of the substrate 100 may include a first n-type metal layer pattern 110a, a first barrier metal layer pattern 114a, a first electrode layer pattern 116a, and a first insulating mask layer pattern 118a, sequentially stacked on a first gate dielectric 106a (that includes a high-k dielectric material).

The second gate structure 125b on the PMOS region of the substrate 100 may include a p-type metal layer pattern 108b, a second n-type metal layer pattern 110b, a second barrier metal layer pattern 114b, a second electrode layer pattern 116b, and a second insulating mask layer pattern 118b, sequentially stacked on a second gate dielectric 106b (that includes a high-k dielectric material).

In the first and second gate structures 125a and 125b, the first and second electrode layer patterns 116a and 116b may be directly on the first and second n-type metal layer patterns 110a and 110b, as shown in FIG. 1, or first and second polysilicon layer patterns 112a and 112b may be between the first and second n-type metal layer patterns 110a and 110b and the first and second barrier metal layer patterns 114a and 114b, as shown in FIG. 3.

A distance between, e.g., a minimum distance between, an outer side surface of the second offset pattern 120b and a side surface of the p-type metal layer pattern 108b may be represented by “A”, a thickness of the second offset pattern 120b may be represented by “d”, and “A” may be within the range of or may satisfy the following relation: 0≦A≦d. For example, “A” may correspond to an amount of undercut of the p-type metal layer pattern 108b during a gate-etching process, and may be controlled by changing a condition of the etching process.

When A=0, as shown in FIGS. 1A and 1B, a width w1 of the p-type metal layer pattern 108b may satisfy the following relation: w1=2d+w2 (in which w2 refers to a width of the second n-type metal layer pattern 110b). In this case, the outer side surface of the second offset pattern 120b and the side surface of the p-type metal layer pattern 108b may be collinear, concentric, or aligned with each other.

When A=d, as shown in FIGS. 4A and 4B, the p-type metal layer pattern 108b may have the same width as the second n-type metal layer pattern 110b. In this case, the second offset pattern 120b may or may not be in contact with a top edge of the p-type metal layer pattern 108b.

When A is greater than zero and smaller than d, as shown in FIGS. 5A and 5B, the p-type metal layer pattern 108b may be undercut as much as the value of A from the outer side surface of the second offset pattern 120b.

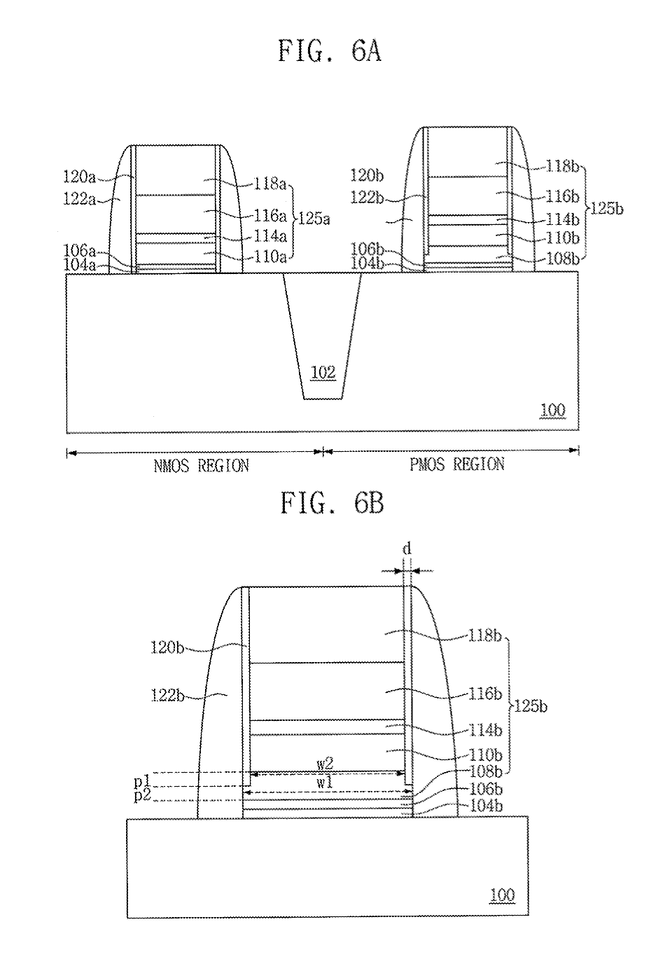

Referring to FIGS. 6A to 8B, a semiconductor device in accordance with an embodiment may include a substrate 100 having an NMOS region and a PMOS region, a trench isolation region 102 in the substrate 100, a first gate structure 125a on the NMOS region of the substrate 100, a second gate structure 125b on the PMOS region of the substrate 100, first and second spacers 122a and 122b on sidewalls of the first and second gate structures 125a and 125b, and first and second offset patterns 120a and 120b between the first gate structure 125a and the first spacer 122a, and between the second gate structure 125b and the second spacer 122b, respectively.

The first gate structure 125a on the NMOS region of the substrate 100 may include a first n-type metal layer pattern 110a, a first barrier metal layer pattern 114a, a first electrode layer pattern 116a, and a first insulating mask layer pattern 118a, sequentially stacked on a first gate dielectric 106a (that includes a high-k dielectric material).

The second gate structure 125b on the PMOS region of the substrate 100 may include a p-type metal layer pattern 108b, a second n-type metal layer pattern 110b, a second barrier metal layer pattern 114b, a second electrode layer pattern 116b, and a second insulating mask layer pattern 118b, sequentially stacked on a second gate dielectric 106b (that includes a high-k dielectric material).

The second offset pattern 120b may be on the sidewalls of the second gate structure 125b, excluding a portion of sidewalls of the p-type metal layer pattern 108b. For example, the second offset pattern 120b may be on sidewalls of the second n-type metal layer pattern 110b, the second barrier metal layer pattern 114b, the second electrode layer pattern 116b, the second insulating mask layer pattern 118b, and a portion of the p-type metal layer pattern 108b. In an implementation, the second offset pattern 120b may be on sidewalls of only the second n-type metal layer pattern 110b, the second barrier metal layer pattern 114b, the second electrode layer pattern 116b, the second insulating mask layer pattern 118b, and a portion of the p-type metal layer pattern 108b. In an implementation, the second offset pattern 120b may have a bottom surface that faces the substrate 100, the p-type metal layer pattern 108b may have a bottom surface that faces the substrate 100, and the bottom surface of the p-type metal layer pattern 108b may be closer to the substrate 100 than the bottom surface of the second offset pattern 120b. In an implementation, the p-type metal layer pattern 108b may have a top surface that faces away from the substrate 100, and the bottom surface of the second offset pattern 120b may be closer to the substrate 100 than the top surface of the p-type metal layer pattern 108b.

For example, the p-type metal layer pattern 108b may include a first part p1 (having a same width w2 as the second n-type metal layer pattern 110b) and a second part p2 (having a width w1 greater than that of the second n-type metal layer pattern 110b). The first part p1 of the p-type metal layer pattern 108b, e.g., sides of the first part p1, may be in contact with the second offset pattern 120b, and the second part p2, e.g., sides of the second part p2, may be in contact with the second spacer 122b. The p-type metal layer pattern 108b may be selectively etched using the second offset pattern 120b in contact with the first part p1 of the p-type metal layer pattern 108b.

The distance between, e.g., a minimum distance between, an outer side surface of the second offset pattern 120b and a side surface of the second part p2 of the p-type metal layer pattern 108b may be represented by “A”, a thickness of the second offset pattern 120b may be represented by “d”, and “A” may be within the range of or may satisfy the following relation: 0≦A≦d.

When A=0, as shown in FIGS. 6A and 6B, the width w1 of the second part p2 of the p-type metal layer pattern 108b may satisfy the following relation: w1=2d+w2. In this case, the outer side surface of the second offset pattern 120b and the side surface of the second part p2 of the p-type metal layer pattern 108b may be, e.g., collinear, concentric, or aligned with each other.

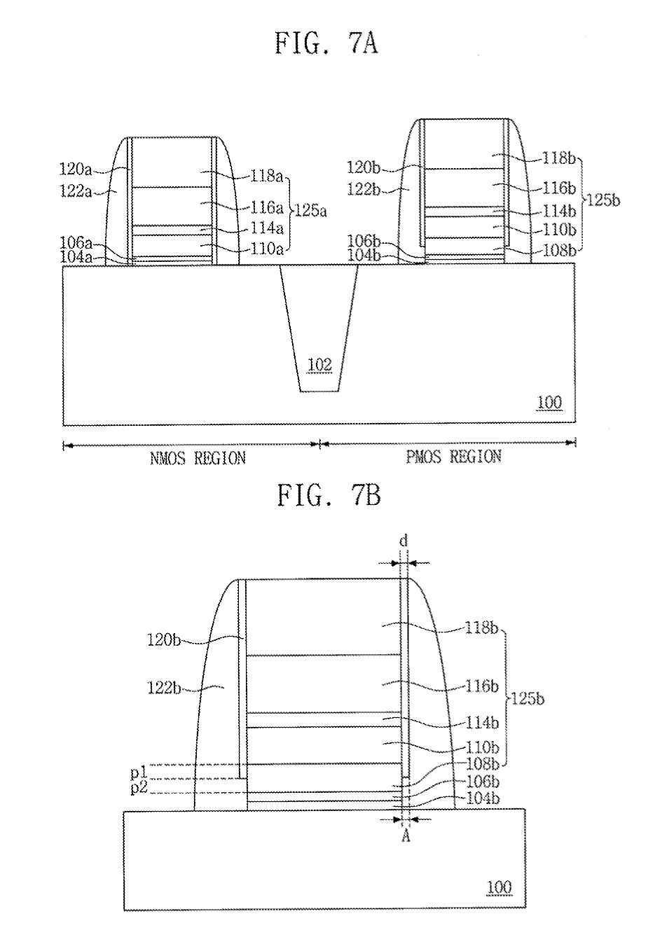

When A=d, as shown in FIGS. 7A and 7B, the first part p1 and the second part p2 of the p-type metal layer pattern 108b may have the same width. For example, the p-type metal layer pattern 108b may have the same width as the second n-type metal layer pattern 110b.

When A is greater than zero and smaller than d, as shown in 8A and 8B, the first part p1 of the p-type metal layer pattern 108b may have the same width as the second n-type metal layer pattern 110b, and the second part p2 of the p-type metal layer pattern 108b may be undercut as much as the value of A from the outer side surface of the second offset pattern 120b.

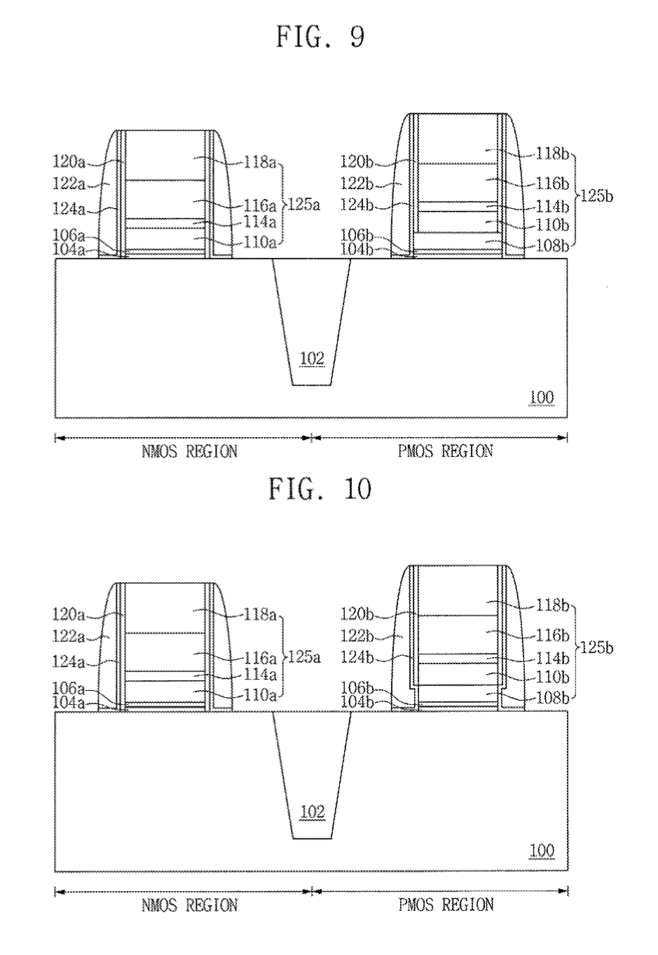

Referring to FIGS. 9 to 11, a semiconductor device in accordance with an embodiment may include a substrate 100 having an NMOS region and a PMOS region, a trench isolation region 102 in the substrate 100, a first gate structure 125a on the NMOS region of the substrate 100, and a second gate structure 125b on the PMOS region of the substrate 100.

The first gate structure 125a on the NMOS region of the substrate 100 may include a first n-type metal layer pattern 110a, a first barrier metal layer pattern 114a, a first electrode layer pattern 116a, and a first insulating mask layer pattern 118a, sequentially stacked on a first gate dielectric 106a (that includes a high-k dielectric material).

The second gate structure 125b on the PMOS region of the substrate 100 may include a p-type metal layer pattern 108b, a second n-type metal layer pattern 110b, a second barrier metal layer pattern 114b, a second electrode layer pattern 116b, and a second insulating mask layer pattern 118b, sequentially stacked on a second gate dielectric 106b (that includes a high-k dielectric material).

First and second spacers 122a and 122b may be formed on sidewalls of the first and second gate structures 125a and 125b, respectively.

First and second offset patterns 120a and 120b may be formed between the first gate structure 125a and the first spacer 122a, and between the second gate structure 125b and the second spacer 122b, respectively. The second offset pattern 120b may be formed on the sidewalls of the second gate structure 125b excluding sidewalls of the p-type metal layer pattern 108b. For example, the second offset pattern 120b may be on sidewalls of the second n-type metal layer pattern 110b, the second barrier metal layer pattern 114b, the second electrode layer pattern 116b, and the second insulating mask layer pattern 118b. In an implementation, the second offset pattern 120b may be on sidewalls of only the second n-type metal layer pattern 110b, the second barrier metal layer pattern 114b, the second electrode layer pattern 116b, and the second insulating mask layer pattern 118b. In an implementation, the second offset pattern 120b may cover at least a portion of a top edge of the p-type metal layer pattern 108b.

A distance between, e.g., a minimum distance between, an outer side surface of the second offset pattern 120b and a side surface of the p-type metal layer pattern 108b may be represented by “A”, a thickness of the second offset pattern 120b may be represented by “d”, and “A” may be within the range of or may satisfy the following relation: 0≦A≦d.

When A=0, as shown in FIG. 9, the outer side surface of the second offset pattern 120b and the side surface of the p-type metal layer pattern 108b may be collinear, concentric, or aligned with each other.

When A=d, as shown in FIG. 10, the p-type metal layer pattern 108b may have the same width as the second n-type metal layer pattern 110b.

When A is greater than zero and smaller than d, as shown in FIG. 11, the p-type metal layer pattern 108b may be undercut as much as the value of A from the side surface of the second offset pattern 120b.

First and second insulating layer patterns 124a and 124b may be between the first offset pattern 120a and the first spacer 122a, and between the second offset pattern 120b and the second spacer 122b, respectively. The first insulating layer pattern 124a may be in contact with a side surface of the first offset pattern 120a. For example, the second insulating layer pattern 124b may be in contact with the side surface of the second offset pattern 120b and the side surface of the p-type metal layer pattern 108b. The first and second insulating layer patterns 124a and 124b may help prevent the side surface of the p-type metal layer pattern 108b from being oxidized or damaged. The first and second insulating layer patterns 124a and 124b may include an insulating material suitable for reducing and/or preventing oxidation of a metal.

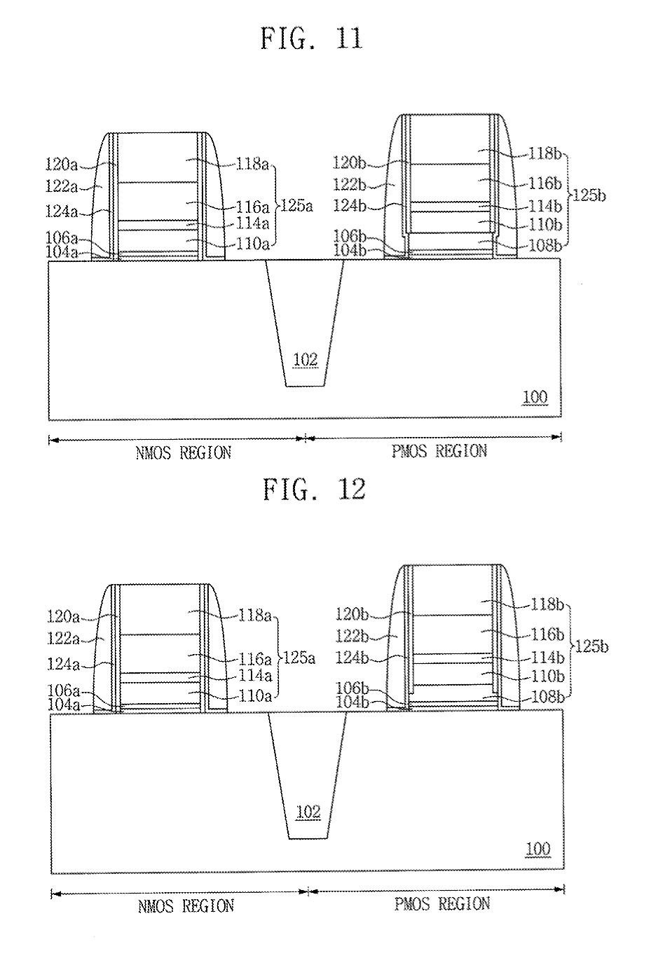

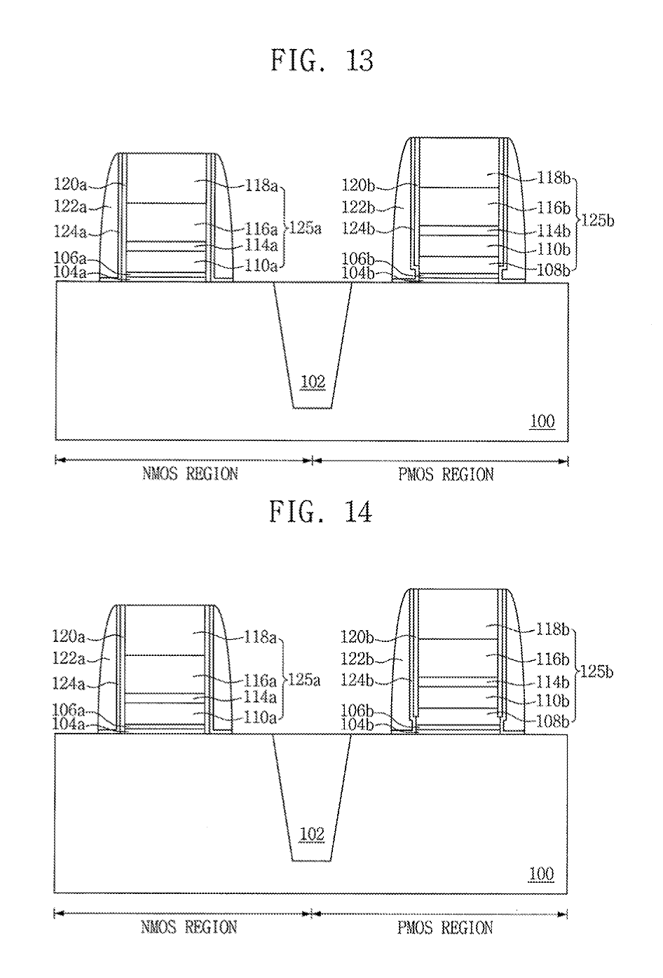

Referring to FIGS. 12 to 14, a semiconductor device in accordance with an embodiment may include a substrate 100 having an NMOS region and a PMOS region, a trench isolation region 102 in the substrate 100, a first gate structure 125a on the NMOS region of the substrate 100, a second gate structure 125b on the PMOS region of the substrate 100, first and second spacers 122a and 122b on sidewalls of the first and second gate structures 125a and 125b, first and second offset patterns 120a and 120b between the first gate structure 125a and the first spacer 122a, and between the second gate structure 125b and the second spacer 122b, and first and second insulating layer patterns 124a and 124b between the first offset pattern 120a and the first spacer 122a, and between the second offset pattern 120b and the second spacer 122b, respectively.

The first gate structure 125a on the NMOS region of the substrate 100 may include a first n-type metal layer pattern 110a, a first barrier metal layer pattern 114a, a first electrode layer pattern 116a, and a first insulating mask layer pattern 118a, sequentially stacked on a first gate dielectric 106a (that includes a high-k dielectric material).

The second gate structure 125b on the PMOS region of the substrate 100 may include a p-type metal layer pattern 108b, a second n-type metal layer pattern 110b, a second barrier metal layer pattern 114b, a second electrode layer pattern 116b, and a second insulating mask layer pattern 118b, sequentially stacked on a second gate dielectric 106b (that includes a high-k dielectric material).

The second offset pattern 120b may be on the sidewalls of the second gate structure 125b, excluding a portion of sidewalls of the p-type metal layer pattern 108b. For example, the second offset pattern 120b may be on sidewalls of the second n-type metal layer pattern 110b, the second barrier metal layer pattern 114b, the second electrode layer pattern 116b, the second insulating mask layer pattern 118b, and a portion of the p-type metal layer pattern 108b. In an implementation, the second offset pattern 120b may be on sidewalls of only the second n-type metal layer pattern 110b, the second barrier metal layer pattern 114b, the second electrode layer pattern 116b, the second insulating mask layer pattern 118b, and a portion of the p-type metal layer pattern 108b. In an implementation, the second offset pattern 120b may have a bottom surface that faces the substrate 100, the p-type metal layer pattern 108b may have a bottom surface that faces the substrate 100, and the bottom surface of the p-type metal layer pattern 108b may be closer to the substrate 100 than the bottom surface of the second offset pattern 120b. In an implementation, the p-type metal layer pattern 108b may have a top surface that faces away from the substrate 100, and the bottom surface of the second offset pattern 120b may be closer to the substrate 100 than the top surface of the p-type metal layer pattern 108b.

For example, the p-type metal layer pattern 108b may include a first part p1 (having the same width w2 as the second n-type metal layer pattern 110b) and a second part p2 (having a greater width w1 than the second n-type metal layer pattern 110b). The second offset pattern 120b may be in contact with the first part p1 of the p-type metal layer pattern 108b, e.g., sides of the first part p1. The second part p2 of the p-type metal layer pattern 108b, e.g., sides of the second part p2, may be in contact with the second spacer 122b.

A distance between, e.g., a minimum distance between, an outer side surface of the second offset pattern 120b and a side surface of the second part p2 of the p-type metal layer pattern 108b may be represented by A, the thickness of the second offset pattern 120b may be represented by d, and A may be within the range of or may satisfy the following relation: 0≦A≦d.

When A=0, as shown in FIG. 12, the outer side surface of the second offset pattern 120b and the side surface of the second part p2 of the p-type metal layer pattern 108b may be collinear, concentric, or aligned with each other.

When A=d, as shown in FIG. 13, the p-type metal layer pattern 108b may have the same width as the second n-type metal layer pattern 110b.

When A is greater than zero and smaller than d, as shown in FIG. 14, the first part p1 of the p-type metal layer pattern 108b may have the same width as the second n-type metal layer pattern 110b, and the second part p2 of the p-type metal layer pattern 108b may be undercut as much as the value of A from the side surface of the second offset pattern 120b.

The second insulating layer pattern 124b may be in contact with the side surface of the second offset pattern 120b and the side surface of the second part p2 of the p-type metal layer pattern 108b.

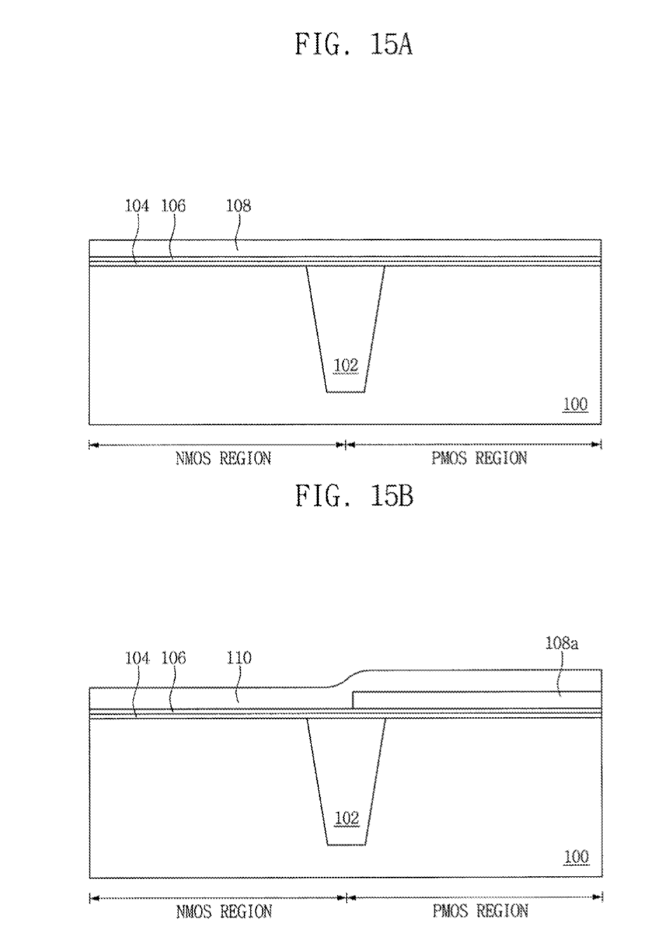

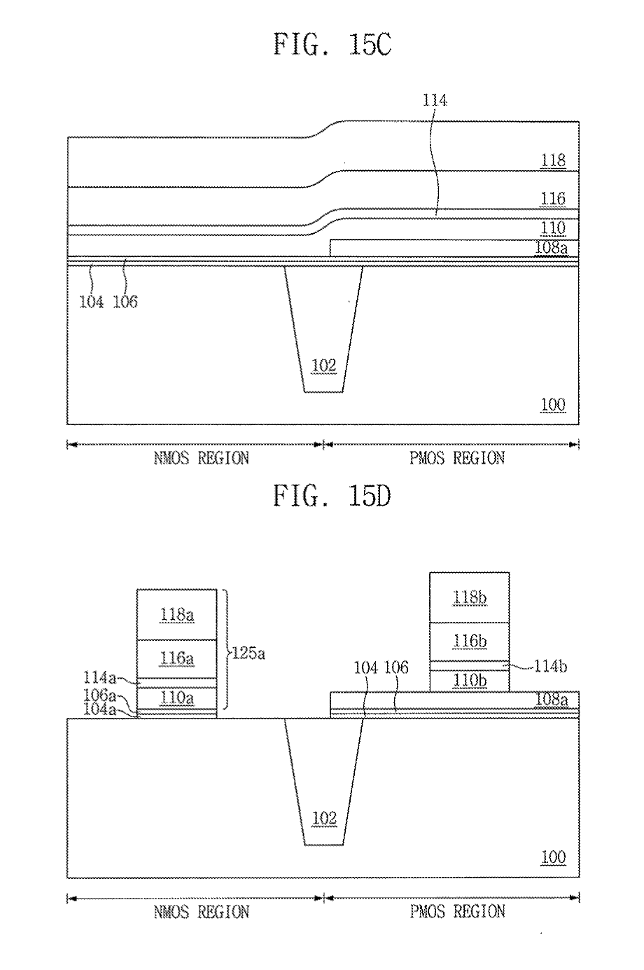

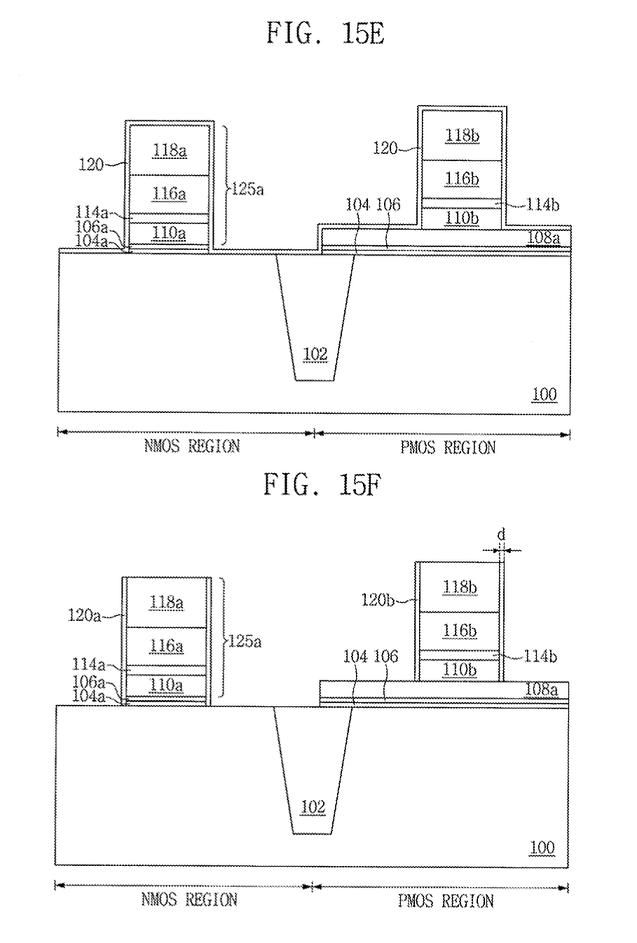

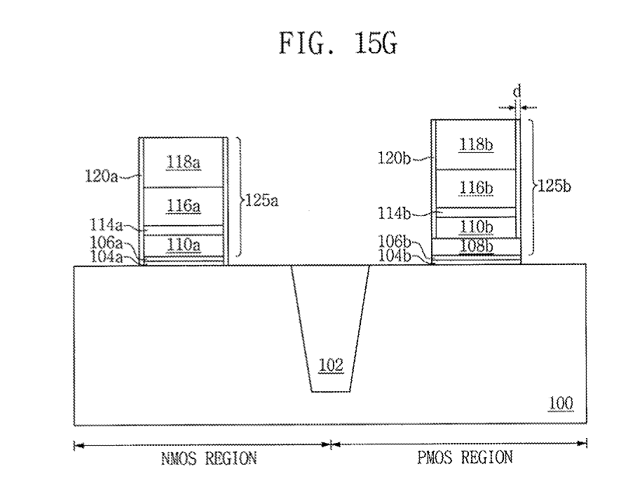

FIGS. 15A to 26 illustrate cross-sectional views of stages in a method of fabricating semiconductor devices in accordance with various embodiments.

FIGS. 15A to 17 illustrate cross-sectional views of stages in a method of fabricating a semiconductor device in accordance with an embodiment.

Referring to FIG. 15A, the method of fabricating a semiconductor device in accordance with an embodiment may include forming a trench isolation region 102 in a substrate 100 (that has an NMOS region and a PMOS region), and sequentially forming an interlayer insulating layer 104, a gate dielectric layer 106, and a p-type metal layer 108 on the substrate 100.

The substrate 100 may be a semiconductor substrate, e.g., silicon, germanium, and silicon-germanium.

The formation of the trench isolation region 102 may include forming a trench by etching the substrate 100, filling the trench with an insulating layer (including, e.g., silicon oxide), and planarizing the substrate 100.

After the formation of the trench isolation region 102, a P-well (defining the NMOS region) and an N-well (defining the PMOS region) may be formed in the substrate 100.

The interlayer insulating layer 104 may be a layer that helps reduce interfacial traps between the substrate 100 and the gate dielectric layer 106 and that helps maintain a mobility of carriers. The interlayer insulating layer 104 may include, e.g., silicon oxide (SiOₓ) or silicon oxynitride (SiON). The interlayer insulating layer 104 may be formed by an oxidation process.

The gate dielectric layer 106 may include a high-k dielectric material having a higher dielectric constant than silicon oxide. For example, the gate dielectric layer 106 may include a suitable high-k dielectric material, such as Al₂O₃, HfO₂, HfSiO₂, ZrO₂, ZrSiO, LaO₂, or TiO₂.

The p-type metal layer 108 may be a layer that helps control a threshold voltage of the PMOS device. The p-type metal layer 108 may be formed in a multi-layered structure in which a plurality of thin metal layers are stacked. For example, the p-type metal layer 108 may include at least one of Al₂O₃/TiN, Al₂O₃/TaN, Al/TiN, Al/TaN, TiN/Al/TiN, TaN/Al/TaN, TiN/TiON, TaN/TiON, Ta/TiN, or TaN/TiN.

Referring to FIG. 15B, the method may include forming a p-type metal layer remaining part 108a only in the PMOS region by selectively removing the p-type metal layer 108 of the NMOS region using a photolithography and etching process, and forming an n-type metal layer 110 on the entire surface of the substrate 100.

The n-type metal layer 110 may be a layer that helps control a threshold voltage of the NMOS device. The n-type metal layer 110 may include at least one of TiN/TiON, Mg/TiN, TiN/Mg/TiN, La/TiN, TiN/La/TiN, Sr/TiN, and TiN/Sr/TiN. Here, TaN may be used instead of TiN.

Referring to FIG. 15C, the method may include sequentially forming a barrier metal layer 114, an electrode layer 116, and an insulating mask layer 118 on the n-type metal layer 110.

The barrier metal layer 114 may include at least one of a conductive metal-nitride such as TiN, TaN, and WN, or a conductive metal-semiconductor compound such as a metal silicide.

The electrode layer 116 may be an electrical gate of the NMOS device and the PMOS device, and may include a metal, such as tungsten (W), copper (Cu), or aluminum (Al).

The insulating mask layer 118 may include an insulating material, such as silicon nitride.

Before forming the barrier metal layer 114, a polysilicon layer may be formed on the n-type metal layer 110.

Referring to FIG. 15D, the method may include forming a first gate structure 125a on the NMOS region by etching the insulating mask layer 118, the electrode layer 116, the barrier metal layer 114, and the n-type metal layer 110 using a photolithography and etching process for gate-patterning.

The first gate structure 125a may include a first insulating mask layer pattern 118a, a first electrode layer pattern 116a, a first barrier metal layer pattern 114a, and a first n-type metal layer pattern 110a.

During the etching process, the gate dielectric layer 106 and interlayer insulating layer 104 of the NMOS region may be etched together to form a first gate dielectric 106a and a first interlayer insulating layer pattern 104a.

The etching process may be controlled to stop on the p-type metal layer remaining part 108a, the p-type metal layer remaining part 108a may remain with a uniform thickness while a second insulating mask layer pattern 118b, and a second electrode layer pattern 116b, a second barrier metal layer pattern 114b, and a second n-type metal layer pattern 110b may be formed on the PMOS region.

Referring to FIG. 15E, the method may include forming an offset layer 120 on the entire surface of the substrate 100 having the first gate structure 125a.

The offset layer 120 may be a layer for controlling a distance between a gate and an LDD region. The offset layer 120 may include at least one of silicon nitride, silicon oxide, or silicon oxynitride.

Referring to FIG. 15F, the method may include forming a first offset pattern 120a on a sidewall of the first gate structure 125a by etching the offset layer 120, and at the same time forming a second offset pattern 120b on sidewalls of the second insulating mask layer pattern 118b, the second electrode layer pattern 116b, the second barrier metal layer pattern 114b, and the second n-type metal layer pattern 110b.

Referring to FIG. 15G, the method may include forming a second gate structure 125b on the PMOS region by selectively etching the p-type metal layer remaining part 108a using the second offset pattern 120b as an etch mask.

The p-type metal layer remaining part 108a may be selectively etched using the second offset pattern 120b. Thus, non-etching of the p-type metal layer remaining part 108a and/or undercutting of the first n-type metal layer pattern 110a of the NMOS region may be reduced and/or prevented.

The second gate structure 125b may include a second insulating mask layer pattern 118b, a second electrode layer pattern 116b, a second barrier metal layer pattern 114b, a second n-type metal layer pattern 110b, and a p-type metal layer pattern 108b.

The second offset pattern 120b may be formed on the sidewalls of the second gate structure 125b, excluding sidewalls of the p-type metal layer pattern 108b. For example, the second offset pattern 120b may be formed on sidewalls of the second n-type metal layer pattern 110b, the second barrier metal layer pattern 114b, the second electrode layer pattern 116b, and the second insulating mask layer pattern 118b. In an implementation, the second offset pattern 120b may be formed only on sidewalls of the second n-type metal layer pattern 110b, the second barrier metal layer pattern 114b, the second electrode layer pattern 116b, and the second insulating mask layer pattern 118b. The second offset pattern 120b may be formed to cover a portion of top edge of the p-type metal layer pattern 108b.

The process of selectively etching the p-type metal layer remaining part 108a may be performed using one of a wet etch process or a dry etch process. When using the wet etch process, an SC1 solution, a diluted H₂O₂ solution, an SC2 solution, or the like may be used.

After forming the second gate structure 125b, a wet etch process using a diluted HF solution or the like may be additionally performed. As a result, the gate dielectric layer 106 and interlayer insulating layer 104 of the PMOS region may be etched to form a second gate dielectric 106b and a second interlayer insulating layer pattern 104b.

The process of selectively etching the p-type metal layer remaining part 108a may be performed in such a way that an undercut of the p-type metal layer pattern 108b is formed under the second offset pattern 120b. When the thickness of the second offset pattern 120b is represented by d, and an amount of undercut of the p-type metal layer pattern 108b is represented by A, then A may be controlled to be within the range of or to satisfy the relation: 0≦A≦d, by changing conditions of the etch process.

When A=0, as shown in FIG. 15G, outer side surfaces of the second offset pattern 120b and the p-type metal layer pattern 108b may be collinear, concentric, or aligned with each other.

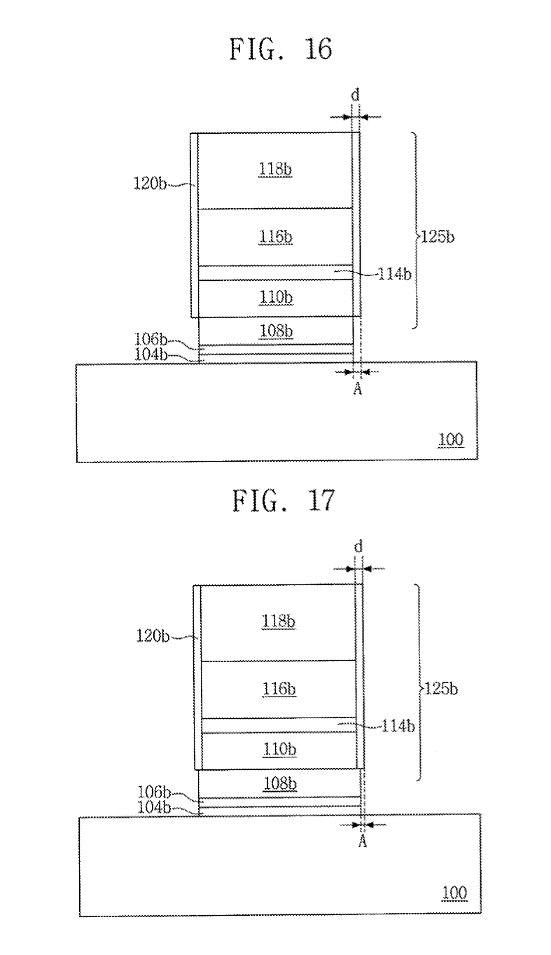

When A=d, as shown in FIG. 16, the p-type metal layer pattern 108b may have the same width as the second n-type metal layer pattern 110b. In this case, the second offset pattern 120b may or may not be in contact with the top edge of the p-type metal layer pattern 108b.

When A is greater than zero and smaller than d, as shown in FIG. 17, the p-type metal layer pattern 108b may be undercut as much as the value A from the outer side surface of the second offset pattern 120b.

After forming the second gate structure 125b, an LDD ion-implantation process may be performed on each of the NMOS region and the PMOS region. As a result, LDD regions aligned with the first and second offset patterns 120a and 120b may be formed.

A spacer layer (including silicon oxide or the like) may be formed on the entire surface of the substrate 100. Then, the spacer layer etched away to form the first and second spacers (see 122a and 122b in FIG. 4) on the sidewalls of the first and second gate structures 125a and 125b.

Next, NMOS and PMOS devices including gates and source/drains may be formed by performing a source/drain ion-implantation process in the NMOS region and the PMOS region.

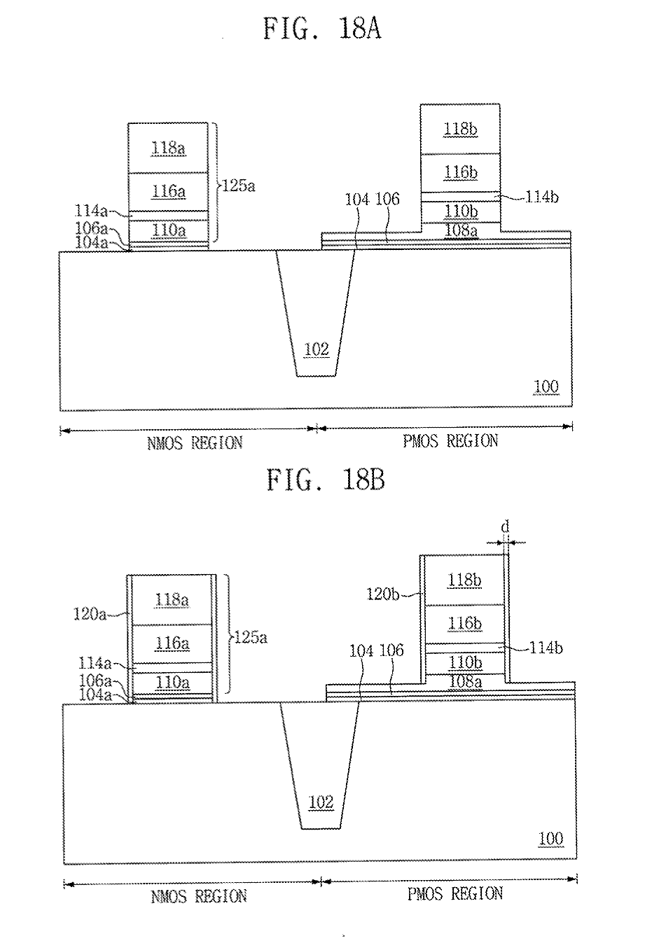

FIGS. 18A to 20 illustrate cross-sectional views of stages in a method of fabricating a semiconductor device in accordance with an embodiment.

Referring to FIG. 18A, the method of fabricating a semiconductor device in accordance with an embodiment may include forming a trench isolation region 102 in a substrate 100 having an NMOS region and a PMOS region, and sequentially stacking an interlayer insulating layer 104, a gate dielectric layer 106, a p-type metal layer 108, an n-type metal layer 110, a barrier metal layer 114, an electrode layer 116, and an insulating mask layer 118 on the substrate 100 by performing processes described with reference to FIGS. 15A to 15C.

The p-type metal layer 108 may be etched to form a p-type metal layer remaining part 108a on the PMOS region, and then, the stacked layers may be etched to form a first gate structure 125a on the NMOS region.

The etching process of forming the first gate structure 125a may be controlled to stop at a predetermined part, e.g., at a middle part, of the p-type metal layer remaining part 108a. Accordingly, a second insulating mask layer pattern 118b, a second electrode layer pattern 116b, a second barrier metal layer pattern 114b, and a second n-type metal layer pattern 110b may be formed on the PMOS region, and the p-type metal layer remaining part 108a may remain in a shape having a convex portion.

Referring to FIG. 18B, the method may include forming a first offset pattern 120a on a sidewall of the first gate structure 125a and, at the same time, forming a second offset pattern 120b on sidewalls of the second insulating mask layer pattern 118b, the second electrode layer pattern 116b, the second barrier metal layer pattern 114b, and the second n-type metal layer pattern 110b, by performing the processes described with reference to FIGS. 15E and 15F.

Referring to FIG. 18C, the method may include forming a second gate structure 125b on the PMOS region by selectively etching the p-type metal layer remaining part 108a using the second offset pattern 120b as an etch mask.

The second gate structure 125b may include a second insulating mask layer pattern 118b, a second electrode layer pattern 116b, a second barrier metal layer pattern 114b, a second n-type metal layer pattern 110b, and a p-type metal layer pattern 108b. The p-type metal layer pattern 108b may include a first part having the same width as the second n-type metal layer pattern 110b, and a second part having a width greater than that of the second n-type metal layer pattern 110b.

After forming the second gate structure 125b, the gate dielectric layer 106 and interlayer insulating layer 104 of the PMOS region may be etched to form a second gate dielectric 106b and a second interlayer insulating layer pattern 104b.

The second offset pattern 120b may be formed on the sidewalls of the second gate structure 125b, excluding a portion of sidewalls of the p-type metal layer pattern 108b. For example, the second offset pattern 120b may be on sidewalls of the second n-type metal layer pattern 110b, the second barrier metal layer pattern 114b, the second electrode layer pattern 116b, the second insulating mask layer pattern 118b, and a portion of the p-type metal layer pattern 108b. In an implementation, the second offset pattern 120b may be on sidewalls of only the second n-type metal layer pattern 110b, the second barrier metal layer pattern 114b, the second electrode layer pattern 116b, the second insulating mask layer pattern 118b, and a portion of the p-type metal layer pattern 108b. The second offset pattern 120b may be in contact with the first part of the p-type metal layer pattern 108b.

The process of selectively etching the p-type metal layer remaining part 108a may be performed in such a way that an undercut is formed at the second part of the p-type metal layer pattern 108b under the second offset pattern 120b. When the thickness of the second offset pattern 120b is represented by d, and the amount of undercut of the second part of the p-type metal layer pattern 108b is represented by A, A may be within the range of or may satisfy the relation: 0≦A≦d, by changing conditions of the etch process.

When A=0, outer side surfaces of the second offset pattern 120b and the second part of the p-type metal layer pattern 108b may be collinear, concentric, or aligned with each other, as shown in FIG. 18C.

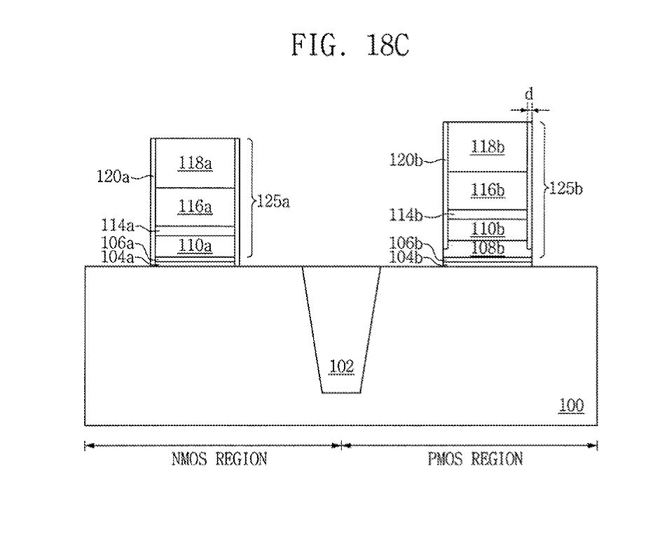

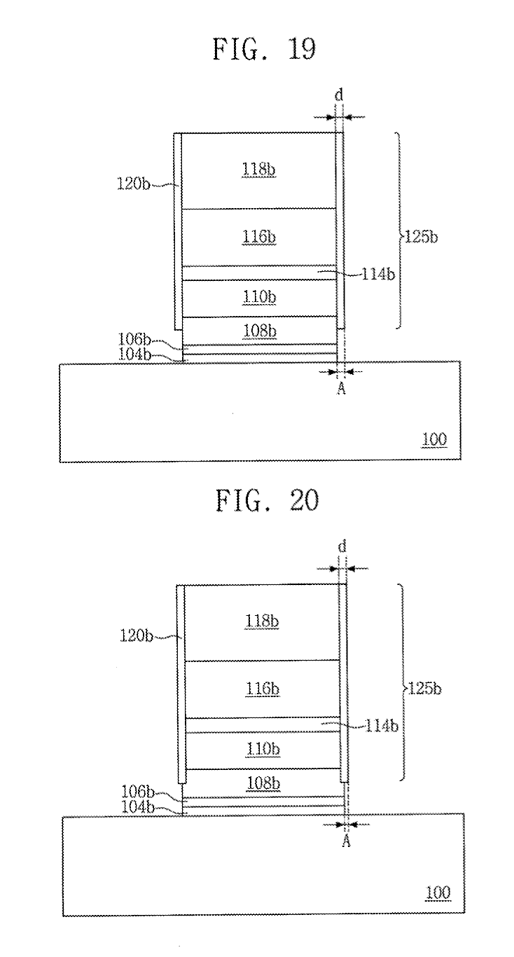

When A=d, the first part and the second part of the p-type metal layer pattern 108b may have the same width, as shown in FIG. 19.

When A is greater than zero and smaller than d, the second part of the p-type metal layer pattern 108b may be undercut as much as the value A from the outer side surface of the second offset pattern 120b, as shown in FIG. 20.

After forming the second gate structure 125b, an LDD ion-implantation process, a spacer formation process, and a source/drain ion-implantation process may be performed.

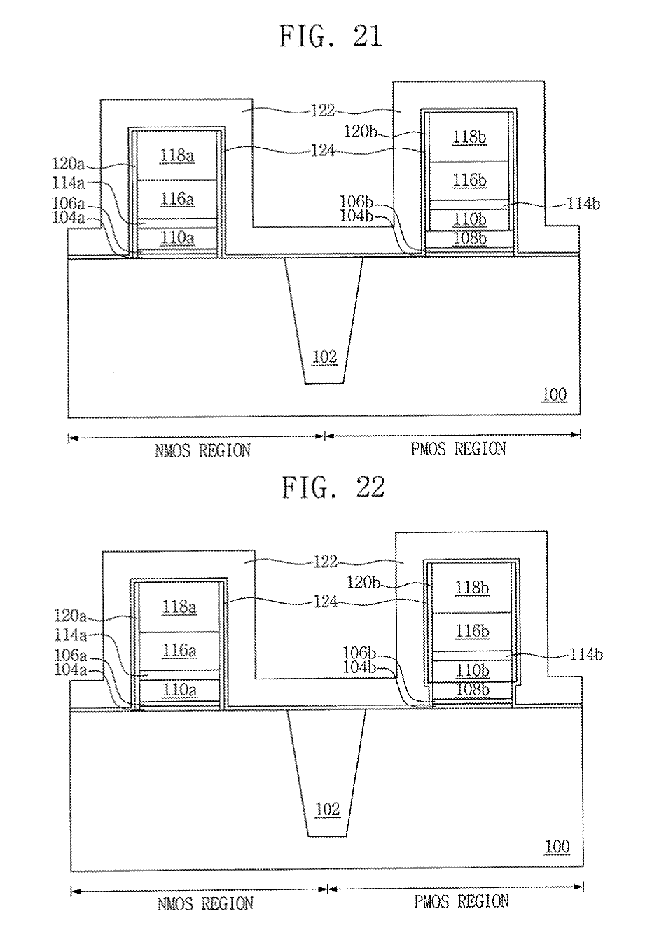

FIGS. 21 to 23 illustrate cross-sectional views of stages a method of fabricating a semiconductor device in accordance with an embodiment.

Referring to FIG. 21, the method of fabricating a semiconductor device in accordance with an embodiment may include forming first and second gate structures 125a and 125b on NMOS and PMOS regions of a substrate 100, and forming first and second offset patterns 120a and 120b on sidewalls of the first and second gate structures 125a and 125b by performing processes described with reference to FIGS. 15A to 15G.

When the amount of undercut of the p-type metal layer pattern 108b under the second offset pattern 120b is represented by A, and the thickness of the second offset pattern 120b is represented by d, A may be within the range of or may satisfy the relation: 0≦A≦d.

When A=0, as shown in FIG. 21, an outer side surface of the second offset pattern 120b and a side surface of the p-type metal layer pattern 108b may be collinear, concentric, or aligned with each other.

When A=d, as shown in FIG. 22, the p-type metal layer pattern 108b may have the same width as the second n-type metal layer pattern 110b.

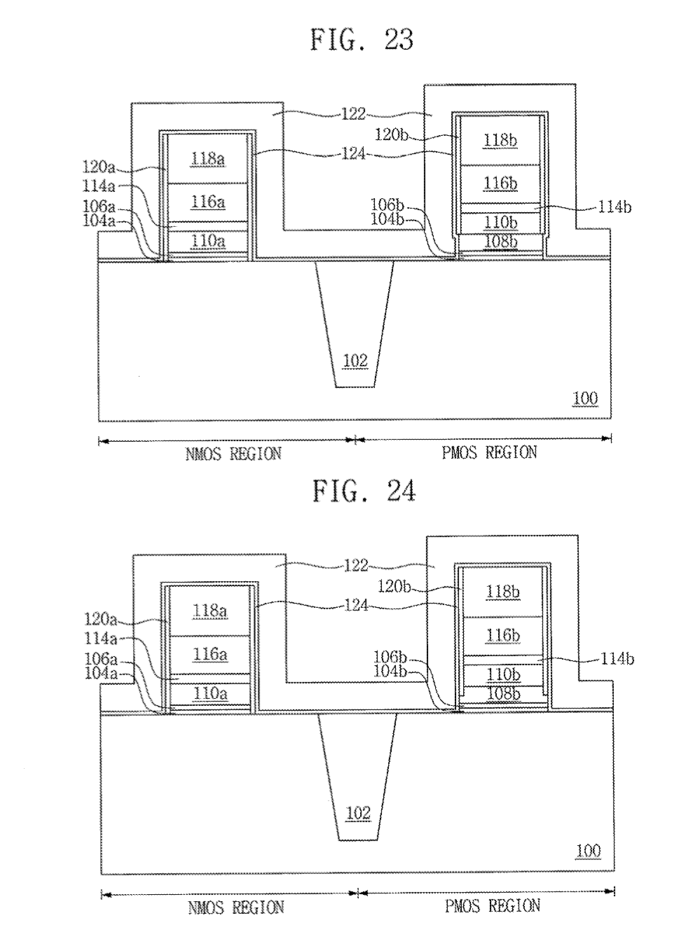

When A is greater than zero and smaller than d, as shown in FIG. 23, the p-type metal layer pattern 108b may be undercut as much as the value of A from the side surface of the second offset pattern 120b.

After forming the first and second offset patterns 120a and 120b, an insulating layer 124 may be formed on the entire surface of the substrate 100. The insulating layer 124 may be in contact with the side surface of the p-type metal layer pattern 108b as shown in FIGS. 21 to 23, and damage or oxidation of the side surface of the p-type metal layer pattern 108b may be reduced and/or prevented. The insulating layer 124 may include an insulating material, e.g., silicon nitride, which helps prevent oxidation of a metal.

After forming the insulating layer 124, a spacer layer 122 may be formed on the entire surface of the substrate 100. Next, the spacer layer 122 may be etched to form first and second spacers (see 122a and 122b in FIG. 9) on the sidewalls of the first and second gate structures 125a and 125b. During a process of etching the spacer layer 122, the insulating layer 124 may also be etched to form first and second insulating layer patterns (see 124a and 124b in FIG. 9). The first insulating layer pattern 124a may be in contact with a side surface of the first offset pattern 120a, and the second insulating layer pattern 124b may be in contact with the side surfaces of the second offset pattern 120b and p-type metal layer pattern 108b.

FIGS. 24 to 26 illustrate cross-sectional views of stages in a method of fabricating a semiconductor device in accordance with an embodiment.

Referring to FIG. 24, the method may include forming first and second gate structures 125a and 125b on NMOS and PMOS regions of a substrate 100, and forming first and second offset patterns 120a and 120b on sidewalls of the first and second gate structures 125a and 125b by performing processes described with reference to FIGS. 15A to 15G.

The p-type metal layer pattern 108b of the second gate structure 125b may include a first part (having the same width as the second n-type metal layer pattern 110b) and a second part (having a greater width than the second n-type metal layer pattern 110b).

When the amount of undercut of the second part of the p-type metal layer pattern 108b under the second offset pattern 120b is represented by A, and the thickness of the second offset pattern 120b is represented by d, A may be within the range of or may satisfy the relation: 0≦A≦d.

When A=0, as shown in FIG. 24, an outer side surface of the second offset pattern 120b and a side surface of the second part of the p-type metal layer pattern 108b may be collinear, concentric, or aligned with each other.

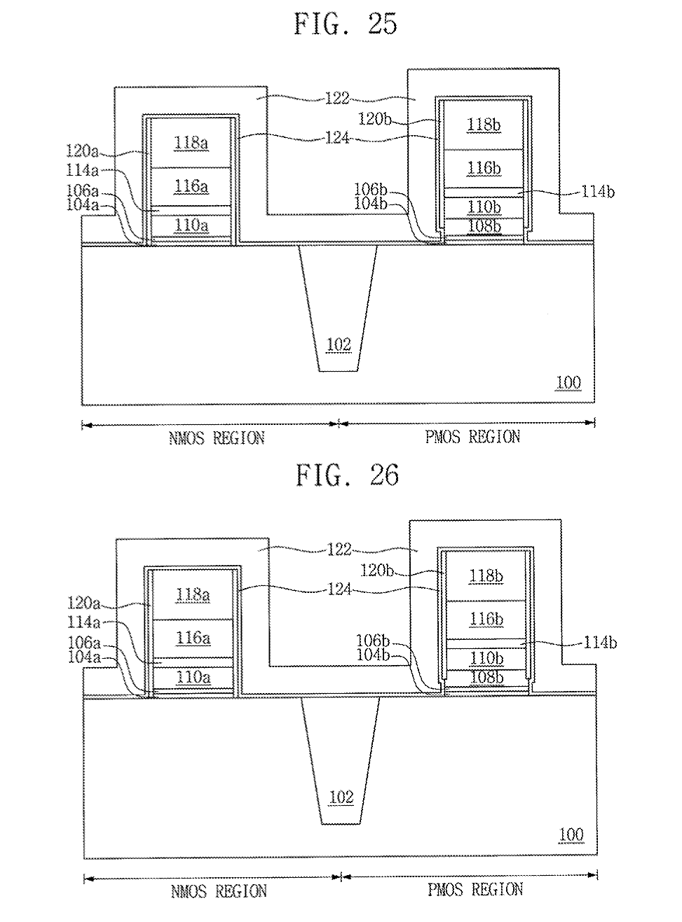

When A=d, as shown in FIG. 25, the first part and the second part of the p-type metal layer pattern 108b may have the same width.

When A is greater than zero and smaller than d, as shown in FIG. 26, the second part of the p-type metal layer pattern 108b may be undercut as much as the value of A from the side surface of the second offset pattern 120b.

After forming the first and second offset patterns 120a and 120b, an insulating layer 124 may be formed on the entire surface of the substrate 100. The insulating layer 124 may be formed to be in contact with a side surface of the second part of the p-type metal layer pattern 108b, as shown in FIGS. 24 to 26.

After forming the insulating layer 124, a spacer layer 122 may be formed on the entire surface of the substrate 100.

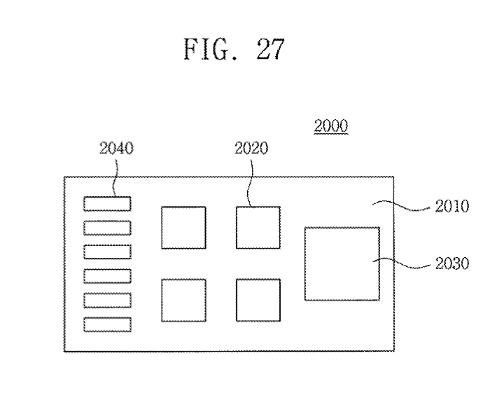

FIG. 27 illustrates a block diagram of a semiconductor module including a semiconductor device in accordance with various embodiments.

Referring to FIG. 27, a semiconductor module 2000 including a control unit 2020, storage unit 2030, and input/output parts 2040 arranged on a module substrate 2010, may be provided.

The module substrate 2010 may include a printed circuit board (PCB).

The control unit 2020 may include a logic device, such as a controller.

The storage unit 2030 may include a memory device, such as a dynamic random access memory (DRAM), a magnetic RAM (MRAM), or a NAND flash.

The input/output parts 2040 may include conductive terminals.

One of the control unit 2020 or the storage unit 2030 may include a semiconductor device in accordance with various embodiments of the inventive concept, or a semiconductor device fabricated by a method of manufacturing a semiconductor device in accordance with various embodiments of the inventive concept.

The semiconductor module 2000 may be a memory card, such as a solid state disk (SSD).

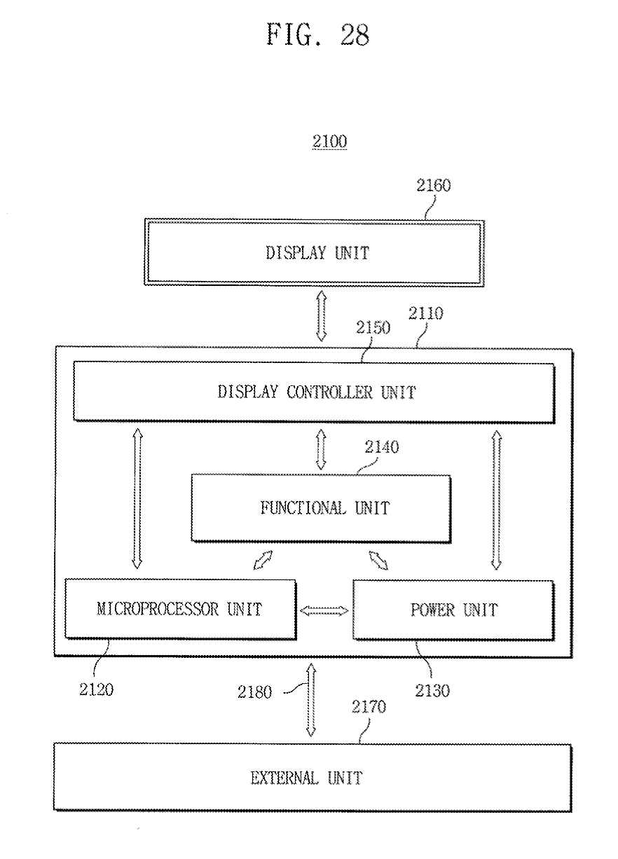

FIG. 28 illustrates a block diagram of an electronic system including a semiconductor device in accordance with various embodiments.

Referring to FIG. 28, semiconductor devices in accordance with various embodiments of the inventive concept may be applied to an electronic system 2100.

The electronic system 2100 may include a body 2110, a microprocessor unit 2120, a power unit 2130, a function unit 2140, and/or a display controller unit 2150.

The body 2110 may be a system board or a motherboard including a printed circuit board (PCB), or the like.

The microprocessor unit 2120, the power unit 2130, the function unit 2140, and the display controller unit 2150 may be mounted or installed on the body 2110.

A display unit 2160 may be arranged on an upper surface or outside of the body 2110. For example, the display unit 2160 may be arranged on a surface of the body 2110 and display an image processed by the display controller unit 2150.

The power unit 2130 may receive a constant voltage from an external battery, or the like, divide the voltage into various levels, and supply those voltages to the microprocessor unit 2120, the function unit 2140, and the display controller unit 2150, or the like.

The microprocessor unit 2120 may receive a voltage from the power unit 2130 to control the function unit 2140 and the display unit 2160.

The function unit 2140 may perform various functions of the electronic system 2100. For example, when the electronic system 2100 is a mobile electronic product such as a mobile phone, the function unit 2140 may have several components which perform wireless communication functions, such as output of an image to the display unit 2160 or output of a voice to a speaker, by dialing or communication with an external apparatus 2170. If a camera is installed, the function unit 2140 may function as a camera image processor.

According to an embodiment, when the electronic system 2100 is connected to a memory card, or the like, in order to expand capacity, the function unit 2140 may be a memory card controller. The function unit 2140 may exchange signals with the external apparatus 2170 through a wired or wireless communication unit 2180.

In addition, when the electronic system 2100 needs a universal serial bus (USB), or the like, in order to expand functionality, the function unit 2140 may function as an interface controller. Further, the function unit 2140 may include a mass storage apparatus.

At least one of the microprocessor unit 2120 or the function unit 2140 may include a semiconductor device in accordance with various embodiments, or a semiconductor device fabricated by a method of manufacturing a semiconductor device in accordance with various embodiments.

According to an embodiment, in a semiconductor device having dual work function metal gates, a second offset pattern of a PMOS device may be formed on sidewalls of a second gate structure, excluding a portion of or the entire sidewalls of a p-type metal layer pattern, while a first offset pattern of an NMOS device is formed on the entire sidewalls of the first gate structure. Using the second offset pattern in contact with a top edge or a portion of a side surface of the p-type metal layer pattern, the p-type metal layer pattern may be selectively etched. Accordingly, a gate etch profile may be improved by preventing that the p-type metal layer of the PMOS device is not etched, or an n-type metal layer of the NMOS device is undercut, during a gate-etching process of the NMOS device and the PMOS device, which have different heights of gate stacks from each other.

By way of summation and review, in a high-k metal gate CMOS device having dual work function, when gates of NMOS and PMOS, which have gate stacks of different heights from each other, are etched at the same time, a p-metal gate of the PMOS having a relatively higher gate stack may be un-etched. In addition, when excessive gate etching is performed in an effort to prevent the p-metal gate from being un-etched, an n-metal gate of the NMOS may be undercut.

An embodiment may provide a gate structure in which an offset spacer of a PMOS is in contact with a top surface or a part of a side of a p-metal gate, by selectively etching the p-metal gate of the PMOS using the offset spacer, after an n-metal gate of an NMOS is fully etched.

The embodiments may provide a semiconductor device having dual work function gate structures.

The embodiments may provide a semiconductor device capable of improving an etch profile of a gate electrode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a substrate including an NMOS region and a PMOS region;
first and second gate dielectrics on the NMOS and PMOS regions of the substrate and including a high-k dielectric material;
a first gate structure on the first gate dielectric and including a sequentially stacked first n-type metal layer pattern and first electrode layer pattern;
a second gate structure on the second gate dielectric and including a sequentially stacked p-type metal layer pattern, second n-type metal layer pattern, and second electrode layer pattern;
first and second spacers on sidewalls of the first and second gate structures;
a first offset pattern between the first gate structure and the first spacer; and
a second offset pattern between the second gate structure and the second spacer, the second offset pattern being on the sidewalls of the second gate structure excluding sidewalls of the p-type metal layer pattern, further comprising:
a first insulating layer pattern between the first offset pattern and the first spacer, and
a second insulating layer pattern between the second offset pattern and the second spacer.

2.-6. (canceled)

7. The semiconductor device as claimed in claim 1, wherein the second insulating layer pattern is in contact with a side surface of the p-type metal layer pattern.

8.-10. (canceled)

11. A semiconductor device, comprising:
a substrate including an NMOS region and a PMOS region;
first and second gate dielectrics on the NMOS and PMOS regions of the substrate and including a high-k dielectric material;
a first gate structure on the first gate dielectric and including a sequentially stacked first n-type metal layer pattern and first electrode layer pattern;
a second gate structure on the second gate dielectric and including a sequentially stacked p-type metal layer pattern, second n-type metal layer pattern, and second electrode layer pattern;
first and second spacers on sidewalls of the first and second gate structures;
a first offset pattern between the first gate structure and the first spacer; and
a second offset pattern between the second gate structure and the second spacer, the second offset pattern being on the sidewalls of the second gate structure excluding a portion of sidewalls of the p-type metal layer pattern.

12. The semiconductor device as claimed in claim 11, wherein the p-type metal layer pattern includes:
a first part having a same width as the second n-type metal layer pattern, and
a second part having a width greater than the second n-type metal layer pattern.

13. The semiconductor device as claimed in claim 11, wherein the second offset pattern is in contact with a side surface of the first part of the p-type metal layer pattern.

14. The semiconductor device as claimed in claim 12, wherein:
a distance between an outer side surface of the second offset pattern and a side surface of the second part of the p-type metal layer pattern is represented by A,
a thickness of the second offset pattern is represented by d, and
A satisfies the following relation: 0≦A≦d.

15. The semiconductor device as claimed in claim 11, further comprising:
a first insulating layer pattern between the first offset pattern and the first spacer, and
a second insulating layer pattern between the second offset pattern and the second spacer,
wherein the second insulating layer pattern is in contact with a side surface of the p-type metal layer pattern.

16. A semiconductor device, comprising:
a substrate including an NMOS region and a PMOS region;
first and second gate dielectrics on the NMOS and PMOS regions of the substrate and including a high-k dielectric material;
a first gate structure on the first gate dielectric and including a sequentially stacked first n-type metal layer pattern and first electrode layer pattern;
a second gate structure on the second gate dielectric and including a sequentially stacked p-type metal layer pattern, second n-type metal layer pattern, and second electrode layer pattern;
first and second spacers on sidewalls of the first and second gate structures;
a first offset pattern between the first gate structure and the first spacer; and
a second offset pattern between the second gate structure and the second spacer, the second offset pattern being on the sidewalls of the second gate structure,
wherein:
the second offset pattern has a bottom surface that faces the substrate,
the p-type metal layer pattern has a bottom surface that faces the substrate, and
the bottom surface of the p-type metal layer pattern is closer to the substrate than the bottom surface of the second offset pattern, wherein.
the p-type metal layer pattern has a top surface that faces away from the substrate, and
the bottom surface of the second offset pattern is closer to the substrate than the top surface of the p-type metal layer pattern.

17. (canceled)

18. The semiconductor device as claimed in claim 16, wherein an outer side surface of the second offset pattern is aligned with a side surface of p-type metal layer pattern.

19.-20. (canceled)
